(19) United States
(12) Patent Application Publication
(10) Pub. No.: US 2026/0352154 A1
(43) Pub. Date: Nov. 5, 2026

(54) Parametric Frequency Comb Generators for Electromechanically Resonant Sensors and Tags

(71) Applicant: Northeastern University, Boston, MA (US)

(72) Inventors: Cristian Cassella, Boston, MA (US); Hussein M.E. Hussein, Boston, MA (US); Luca Colombo, Boston, MA (US); Nicolas Casilli, Kendall Park, NJ (US); Pietro Simeoni, Boston, MA (US); Matteo Rinaldi, Boston, MA (US)

(21) Appl. No.: 19/185,470

(22) Filed: Apr. 22, 2025

Related U.S. Application Data
(60) Provisional application No. 63/637,355, filed on Apr. 22, 2024.
(60) Provisional application No. 63/673,129, filed on Jul. 18, 2024.
(60) Provisional application No. 63/673,287, filed on Jul. 19, 2024.

(51) Int. Cl. H03B 5/32; G06K 19/07

(52) U.S. Cl. CPC H03B 5/32; G06K 19/0723

(57) ABSTRACT

Provided herein are parametric frequency comb generators having a parametric oscillator, an electromechanical resonator coupled to the parametric oscillator, an input for receiving a pump signal, and an output for transmitting a frequency comb, the output either combined with or separate from the input, wherein the parametric frequency comb generator produces the frequency comb centered around an input frequency of the pump signal received by the input, a multiple of the input frequency, or a fraction of the input frequency, and wherein a line spacing of the frequency comb is a function of the input frequency, a power of the pump signal received by the parametric frequency comb generator, a resonance frequency of the resonator, or combinations thereof.

### CROSS REFERENCE TO RELATED APPLICATIONS

This application claims the priority of U.S. Provisional Application No. 63/637,355 filed Apr. 22, 2024 and titled “Parametric Frequency Comb Generator for Analysis of Infrared Resonant Sensors”, U.S. Provisional Application No. 63/673,129 filed Jul. 18, 2024 and titled “Frequency Comb-Based Passive Parametric RFID Tags”, and U.S. Provisional Application No. 63/673,287 filed Jul. 19, 2024 and titled “Frequency Comb-Based Passive Parametric RFID Tags”. The whole of each of the aforementioned provisional applications is hereby incorporated by reference.

### STATEMENT REGARDING FEDERALLY SPONSORED RESEARCH OR DEVELOPMENT

This invention was made with government support under Grant Number DE-AR0001607 awarded by the Department of Energy, under Grant Number HR0011-23-2-0025 awarded by the Defense Advanced Research Projects Agency, and under Grant Number 1854573 awarded by the National Science Foundation. The Government has certain rights in the invention.

### BACKGROUND

Reducing the limit-of-detection (LoD) of sensing systems has been a key priority for a variety of applications. Progress in micro-and nanoelectromechanical (MEM/NEM) resonant technologies has provided key opportunities to improve the achievable LoD by offering high sensitivities and electromechanical performance, such as high quality factors (e.g., Q>1000) and electromechanical coupling coefficients (e.g., kₜ²>0.1%), even when MEM/NEM devices are formed by materials with nm-scale thicknesses. As a result, the most advanced MEM/NEM devices exhibit exceptionally low thermomechanical noise-driven frequency fluctuations, creating a pathway for a quantum-limited LoD when used as sensors.

Typically, resonant MEM/NEM devices are integrated in closed-loop oscillators to serve as reference frequency for read-out. However, the frequency fluctuations (Δfₙ) due to electrical noise originated from the oscillators' active components dominates the MEM/NEM devices' thermomechanical noise. This tremendously degrades the achievable LoD. Yet, to date, there is no existing sensing scheme allowing to read-out the frequency of a resonant sensor placed into a self-sustained motion without using active components in a closed loop. In addition, the miniaturization of the most sensitive MEM/NEM devices pushes the power required to sustain their oscillation into the Watts range, shrinking significantly their field of use, and introducing LoD-degradations due to the limited power handling that compact MEM/NEM devices naturally exhibit and increasing the thermomechanical noise limit.

### SUMMARY OF THE INVENTION

The methods and techniques described herein present circuits, referred to herein as Parametric Frequency Comb Generators (PFCG), for piezoelectric (e.g., AlScN as shown and described herein) electromechanically resonant sensors and tags. The PFCG may generally include an RF parametric oscillator (PO) coupled with an electromechanical resonator.

Such PFCG provide a class of passive devices that may be driven by an input frequency and are configured to respond with a multitude of other frequencies, with those frequencies either centered around or at fraction and multiples of the input frequency. Devices incorporated with a PFCG may be constructed using discrete components, on-chip components, and/or a heterogeneous mixture of electrical components. Such PFCG devices generally include a combination input/output (I/O) and/or separate input and output. Such inputs, outputs, and I/Os can generally be provided as ports, antennas, and/or hardwired connections.

In one aspect, a parametric frequency comb generator is provided. The parametric frequency comb generator includes a parametric oscillator. The parametric frequency comb generator also includes an electromechanical resonator coupled to the parametric oscillator. The parametric frequency comb generator also includes an input for receiving a pump signal. The parametric frequency comb generator also includes an output for transmitting a frequency comb, the output either combined with or separate from the input. The parametric frequency comb generator also includes wherein the parametric frequency comb generator produces the frequency comb centered around an input frequency of the pump signal received by the input, a multiple of the input frequency, or a fraction of the input frequency. The parametric frequency comb generator also includes wherein a line spacing of the frequency comb is a function of the input frequency, a power of the pump signal received by the parametric frequency comb generator, a resonance frequency of the resonator, or combinations thereof.

In some embodiments, the parametric oscillator comprises at least one non-linear element and at least one resonant circuit. In some embodiments, the at least one non-linear element includes one or more of a varactor, a diode, or a combination thereof. In some embodiments, the at least one resonant circuit includes an LC circuit. In some embodiments, the parametric oscillator includes a varactor arranged in a T-network structure with two LC circuits. In some embodiments, the input includes at least one of an input antenna or an input port and the output comprises at least one of a separate output antenna or a separate output port. In some embodiments, the input and output of the device comprise at least one of a combination input/output antenna or a combination input/output port.

In another aspect, a sensing circuit for detection or measurement of a parameter of interest is provided. The sensing circuit includes a parametric frequency comb generator. The parametric frequency comb generator includes a parametric oscillator. The parametric frequency comb generator also includes an electromechanical resonator coupled to the parametric oscillator. The parametric frequency comb generator also includes an input for receiving a pump signal. The parametric frequency comb generator also includes an output for transmitting a frequency comb, the output either combined with or separate from the input. The parametric frequency comb generator also includes wherein the parametric frequency comb generator produces the frequency comb centered around an input frequency of the pump signal received by the input, a multiple of the input frequency, or a fraction of the input frequency. The parametric frequency comb generator also includes wherein a line spacing of the frequency comb is a function of the input frequency, a power of the pump signal received by the parametric frequency comb generator, a resonance frequency of the resonator, or combinations thereof. The sensing circuit also includes at least one sensing element sensitive to the parameter of interest and coupled to the parametric frequency comb generator, wherein a presence, absence, or change of the parameter of interest alters the line spacing of the frequency comb produced by the parametric frequency comb generator.

In some embodiments, the at least one sensing element is sensitive to one or more of a physical parameter, an electrical parameter, a chemical agent, a biological agent, or combinations thereof. In some embodiments, the at least one sensing element is sensitive to a change in one or more of a change in vibration frequency, a change in vibration intensity, a change in temperature, a change in humidity, a change in radiation concentration, a change in radiation energy, a change in radiation intensity, a change in radiation type, a change in acoustic frequency, a change in acoustic intensity, a change in acoustic power, a change in acoustic phase, a change in photonic intensity, a change in photonic frequency, a change in photonic phase, a change in photonic polarization, a change in a change in voltage of an electrical signal, a change in current of an electrical signal, a change in power of an electrical signal, a change in frequency of an electrical signal, a change in a magnetic field, an increase or decrease in a concentration of a chemical agent, a change in presence or absence of a chemical agent, an increase or decrease of a concentration of a biological agent, a change in presence or absence of a biological agent, or combinations thereof. In some embodiments, the at least one sensing element is sensitive to a chemical agent selected from a gas, a toxin, a volatile organic compound, an atmospheric or water-born pollutant, a vehicle emission, an emission of an animal or human, soil moisture, a pharmaceutical agent or formulation ingredient, a polymer, and combinations thereof. In some embodiments, the at least one sensing element is sensitive to a biological agent selected from a bacterium, a virus, a viral vector, a cell, an exosome, an extracellular vesicle, a cellular organelle or cell fragment, an antibody, a protein, a glycoprotein, a nucleic acid, an antigen, a tumor antigen, a sugar, an oligosaccharide, a polysaccharide, a lipid, a glycolipid, a sphingolipid, a vaccine, and combinations thereof. In some embodiments, the at least one sensing element comprises one or more of a thermistor, an infrared detector, a thermocouple, a resistance temperature detector, semiconductor temperature sensors, a current output temperature sensor, a voltage output temperature sensor, a resistance output silicon temperature sensor, a diode temperature sensor, a digital output temperature sensor, or a combination thereof. In some embodiments, the at least one sensing element comprises one or more of a capacitive humidity sensor, a resistive humidity sensor, a thermal conductivity humidity sensor, or a combination thereof. In some embodiments, the at least one sensing element comprises one or more of a scintillation detector, a gamma camera, a gaseous ionization detector, a Geiger Mueller tube, a semiconductor radiation detector, a silicon detector, a diamond detector, a germanium detector, a cadmium telluride detector, a cadmium zinc telluride detector, or combinations thereof. In some embodiments, the at least one sensing element comprises one or more of an image sensor, a charge-coupled device (CCD), an electron-multiplying CCD, a complementary metal-oxide-semiconductor (CMOS), a back-illuminated CMOS, a fiber optic intensity sensor, a fiber optic phase sensor, a fiber optic frequency sensor, a fiber optic polarization sensor, a photoelectric through-beam sensor, a photoelectric retro-reflective sensor, a photoelectric diffuse reflection sensor, an infrared detector, an ultraviolet sensor, an x-ray sensor, a color sensor, an ambient light sensor, a proximity sensor, a photodiode, an avalanche photodiode, a phototransistor, a photomultiplier tube, a spectrometer, or combinations thereof. In some embodiments, the at least one sensing element comprises one or more of a microphone, a piezoelectric transducer, an ultrasonic sensor, an acoustic emission sensor, a surface acoustic wave sensor, a bulk acoustic wave sensor, a capacitive acoustic sensor, or combinations thereof. In some embodiments, the at least one sensing element includes an active or passive element that is sensitive to the parameter of interest. In some embodiments, the parametric frequency comb generator is coupled in series or in parallel with the sensing element. In some embodiments, the sensing circuit is embodied or included in a sensing system. In some embodiments, the sensing system comprises one or more of a camera, a video camera, a telescope, a microscope, a mobile device, a hydrophone, a microphone, a climate control system, a cold chain monitoring system, a radioactivity monitoring system, an environmental monitoring system, a chemical monitoring system, a biological monitoring system, a chemical analysis system, a biological analysis system, a structural monitoring system, a structural analysis system, a medical device, an x-ray machine, an MRI, an ultrasound system, a motion detection system, a range-finding system, a localization system, a target acquisition system, a target tracking system, an object detection system, or combinations thereof. In some embodiments, the input comprises at least one of an input antenna or an input port and the output comprises at least one of a separate output antenna or a separate output port. In some embodiments, the input and output comprise at least one of a combination input/output antenna or a combination input/output port.

In a further aspect, an RFID tag is provided. The RFID tag includes a parametric frequency comb generator. The parametric frequency comb generator includes a parametric oscillator. The parametric frequency comb generator also includes an electromechanical resonator coupled to the parametric oscillator. The parametric frequency comb generator also includes an input for receiving a pump signal. The parametric frequency comb generator also includes an output for transmitting a frequency comb, the output either combined with or separate from the input. The parametric frequency comb generator also includes wherein the parametric frequency comb generator produces the frequency comb centered around an input frequency of the pump signal received by the input, a multiple of the input frequency, or a fraction of the input frequency. The parametric frequency comb generator also includes wherein a line spacing of the frequency comb is a function of the input frequency, a power of the pump signal received by the parametric frequency comb generator, a resonance frequency of the resonator, or combinations thereof.

In some embodiments, the input antenna and the output antenna of the RFID tag are separate antennas. In some embodiments, the input antenna and output antenna of the RFID tag are embodied in a combination input/output antenna. In some embodiments, the RFID tag also includes at least one sensing element sensitive to the parameter of interest and coupled to the parametric frequency comb generator, wherein a change in the parameter of interest alters the line spacing of the frequency comb produced by the parametric frequency comb generator. In some embodiments, the RFID tag is included in a sensing system. In some embodiments, the sensing system comprises one or more of a camera, a video camera, a telescope, a microscope, a mobile device, a hydrophone, a microphone, a climate control system, a cold chain monitoring system, a radioactivity monitoring system, an environmental monitoring system, a chemical monitoring system, a biological monitoring system, a chemical analysis system, a biological analysis system, a structural monitoring system, a structural analysis system, a medical device, an x-ray machine, an MRI, an ultrasound system, a motion detection system, a range-finding system, a localization system, a target acquisition system, a target tracking system, an object detection system, or combinations thereof.

In still another aspect, a method of detecting a presence, absence, or change of a parameter of interest is provided. The method includes providing a sensing circuit for detection or measurement of a parameter of interest. The sensing circuit includes a parametric frequency comb generator. The parametric frequency comb generator includes a parametric oscillator. The parametric frequency comb generator also includes an electromechanical resonator coupled to the parametric oscillator. The parametric frequency comb generator also includes an input for receiving a pump signal. The parametric frequency comb generator also includes an output for transmitting a frequency comb, the output either combined with or separate from the input. The parametric frequency comb generator also includes wherein the parametric frequency comb generator produces the frequency comb centered around an input frequency of the pump signal received by the input, a multiple of the input frequency, or a fraction of the input frequency. The parametric frequency comb generator also includes wherein a line spacing of the frequency comb is a function of the input frequency, a power of the pump signal received by the parametric frequency comb generator, a resonance frequency of the resonator, or combinations thereof. The sensing circuit also includes at least one sensing element sensitive to the parameter of interest and coupled to the parametric frequency comb generator, wherein a presence, absence, or change of the parameter of interest alters the line spacing of the frequency comb produced by the parametric frequency comb generator. The method also includes detecting, by the sensing element, the presence, absence, or change of the parameter of interest. The method also includes receiving, at the sensing circuit, the pump signal having the input frequency. The method also includes outputting, via the sensing circuit, the frequency comb having the altered line spacing. The method also includes determining, from the altered line spacing, the detected presence, absence, or change of the parameter of interest.

Additional features and aspects of the technology include the following:
1. A parametric frequency comb generator comprising:
   a parametric oscillator;
   an electromechanical resonator coupled to the parametric oscillator;
   an input for receiving a pump signal; and
   an output for transmitting a frequency comb, the output either combined with or separate from the input,
   wherein the parametric frequency comb generator produces the frequency comb centered around an input frequency of the pump signal received by the input, a multiple of the input frequency, or a fraction of the input frequency,
   wherein a line spacing of the frequency comb is a function of the input frequency, a power of the pump signal received by the parametric frequency comb generator, a resonance frequency of the resonator, or combinations thereof.
2. The parametric frequency comb generator of feature 1, wherein the parametric oscillator comprises at least one non-linear element and at least one resonant circuit.
3. The parametric frequency comb generator of feature 2, wherein the at least one non-linear element includes one or more of a varactor, a diode, or a combination thereof.
4. The parametric frequency comb generator of any of features 2-3, wherein the at least one resonant circuit includes an LC circuit.
5. The parametric frequency comb generator of any of features 2-4, wherein the parametric oscillator includes a varactor arranged in a T-network structure with two LC circuits.
6. The parametric frequency comb generator of any of features 1-5, wherein the input includes at least one of an input antenna or an input port and the output comprises at least one of a separate output antenna or a separate output port.
7. The parametric frequency comb generator of any of features 1-6, wherein the input and output of the device comprise at least one of a combination input/output antenna or a combination input/output port.
8. A sensing circuit for detection or measurement of a parameter of interest, the sensing circuit comprising:
   a parametric frequency comb generator including:
      a parametric oscillator;
         an electromechanical resonator coupled to the parametric oscillator;
      an input for receiving a pump signal; and
      an output for transmitting a frequency comb, the output either combined with or separate from the input,
      wherein the parametric frequency comb generator produces the frequency comb centered around an input frequency of the pump signal received by the input, a multiple of the input frequency, or a fraction of the input frequency,
      wherein a line spacing of the frequency comb is a function of the input frequency, a power of the pump signal received by the parametric frequency comb generator, a resonance frequency of the resonator, or combinations thereof; and
   at least one sensing element sensitive to the parameter of interest and coupled to the parametric frequency comb generator, wherein a presence, absence, or change of the parameter of interest alters the line spacing of the frequency comb produced by the parametric frequency comb generator.
9. The sensing circuit of feature 8, wherein the at least one sensing element is sensitive to one or more of a physical parameter, an electrical parameter, a chemical agent, a biological agent, or combinations thereof.
10. The sensing circuit of feature 9, wherein the at least one sensing element is sensitive to a change in one or more of a change in vibration frequency, a change in vibration intensity, a change in temperature, a change in humidity, a change in radiation concentration, a change in radiation energy, a change in radiation intensity, a change in radiation type, a change in acoustic frequency, a change in acoustic intensity, a change in acoustic power, a change in acoustic phase, a change in photonic intensity, a change in photonic frequency, a change in photonic phase, a change in photonic polarization, a change in a change in voltage of an electrical signal, a change in current of an electrical signal, a change in power of an electrical signal, a change in frequency of an electrical signal, a change in a magnetic field, an increase or decrease in a concentration of a chemical agent, a change in presence or absence of a chemical agent, an increase or decrease of a concentration of a biological agent, a change in presence or absence of a biological agent, or combinations thereof.
11. The sensing circuit of feature 10, wherein the at least one sensing element is sensitive to a chemical agent selected from a gas, a toxin, a volatile organic compound, an atmospheric or water-born pollutant, a vehicle emission, an emission of an animal or human, soil moisture, a pharmaceutical agent or formulation ingredient, a polymer, and combinations thereof.
12. The sensing circuit of any of features 10-11, wherein the at least one sensing element is sensitive to a biological agent selected from a bacterium, a virus, a viral vector, a cell, an exosome, an extracellular vesicle, a cellular organelle or cell fragment, an antibody, a protein, a glycoprotein, a nucleic acid, an antigen, a tumor antigen, a sugar, an oligosaccharide, a polysaccharide, a lipid, a glycolipid, a sphingolipid, a vaccine, and combinations thereof.
13. The sensing circuit of any of features 10-12, wherein the at least one sensing element comprises one or more of a thermistor, an infrared detector, a thermocouple, a resistance temperature detector, semiconductor temperature sensors, a current output temperature sensor, a voltage output temperature sensor, a resistance output silicon temperature sensor, a diode temperature sensor, a digital output temperature sensor, or a combination thereof.
14. The sensing circuit of any of features 10-13, wherein the at least one sensing element comprises one or more of a capacitive humidity sensor, a resistive humidity sensor, a thermal conductivity humidity sensor, or a combination thereof.
15. The sensing circuit of any of features 10-14, wherein the at least one sensing element comprises one or more of a scintillation detector, a gamma camera, a gaseous ionization detector, a Geiger Mueller tube, a semiconductor radiation detector, a silicon detector, a diamond detector, a germanium detector, a cadmium telluride detector, a cadmium zinc telluride detector, or combinations thereof.
16. The sensing circuit of any of features 10-15, wherein the at least one sensing element comprises one or more of an image sensor, a charge-coupled device, an electron-multiplying CCD, a complementary metal-oxide-semiconductor, a back-illuminated CMOS, a fiber optic intensity sensor, a fiber optic phase sensor, a fiber optic frequency sensor, a fiber optic polarization sensor, a photoelectric through-beam sensor, a photoelectric retro-reflective sensor, a photoelectric diffuse reflection sensor, an infrared detector, an ultraviolet sensor, an x-ray sensor, a color sensor, an ambient light sensor, a proximity sensor, a photodiode, an avalanche photodiode, a phototransistor, a photomultiplier tube, a spectrometer, or combinations thereof.
17. The sensing circuit of any of features 10-16, wherein the at least one sensing element comprises one or more of a microphone, a piezoelectric transducer, an ultrasonic sensor, an acoustic emission sensor, a surface acoustic wave sensor, a bulk acoustic wave sensor, a capacitive acoustic sensor, or combinations thereof.
18. The sensing circuit of any of features 8-17, wherein the at least one sensing element includes an active or passive element that is sensitive to the parameter of interest.
19. The sensing circuit of any of features 8-18, wherein the parametric frequency comb generator is coupled in series or in parallel with the sensing element.
20. The sensing circuit of any of features 8-19, wherein the sensing circuit is embodied or included in a sensing system.
21. The sensing circuit of any of features 8-20, wherein the sensing system comprises one or more of a camera, a video camera, a telescope, a microscope, a mobile device, a hydrophone, a microphone, a climate control system, a cold chain monitoring system, a radioactivity monitoring system, an environmental monitoring system, a chemical monitoring system, a biological monitoring system, a chemical analysis system, a biological analysis system, a structural monitoring system, a structural analysis system, a medical device, an x-ray machine, an MRI, an ultrasound system, a motion detection system, a range-finding system, a localization system, a target acquisition system, a target tracking system, an object detection system, or combinations thereof.
22. The sensing circuit of any of features 8-21, wherein the input comprises at least one of an input antenna or an input port and the output comprises at least one of a separate output antenna or a separate output port.
23. The sensing circuit of any of features 8-22, wherein the input and output comprise at least one of a combination input/output antenna or a combination input/output port.
24. An RFID tag comprising:
   a parametric frequency comb generator including:
      a parametric oscillator;
      an electromechanical resonator coupled to the parametric oscillator;
      an input antenna for receiving an interrogation signal; and
      an output antenna for transmitting a frequency comb, the output antenna either combined with or separate from the input,
      wherein the parametric frequency comb generator produces the frequency comb centered around an input frequency of the interrogation signal received by the input, a multiple of the input frequency, or a fraction of the input frequency,
      wherein a line spacing of the frequency comb is a function of the input frequency, a power of the interrogation signal received by the parametric frequency comb generator, a resonance frequency of the resonator, or combinations thereof.
25. The device of feature 24, wherein the input antenna and the output antenna of the RFID tag are separate antennas.
26. The device of feature 24, wherein the input antenna and output antenna of the RFID tag are embodied in a combination input/output antenna.
27. The RFID tag of any of features 24-26, further comprising at least one sensing element sensitive to the parameter of interest and coupled to the parametric frequency comb generator, wherein a change in the parameter of interest alters the line spacing of the frequency comb produced by the parametric frequency comb generator.
28. The RFID tag of feature 27, wherein the RFID tag is included in a sensing system.
29. The RFID tag of feature 28, wherein the sensing system comprises one or more of a camera, a video camera, a telescope, a microscope, a mobile device, a hydrophone, a microphone, a climate control system, a cold chain monitoring system, a radioactivity monitoring system, an environmental monitoring system, a chemical monitoring system, a biological monitoring system, a chemical analysis system, a biological analysis system, a structural monitoring system, a structural analysis system, a medical device, an x-ray machine, an MRI, an ultrasound system, a motion detection system, a range-finding system, a localization system, a target acquisition system, a target tracking system, an object detection system, or combinations thereof.
30. A method of detecting a presence, absence, or change of a parameter of interest comprising:
   providing a sensing circuit for detection or measurement of a parameter of interest, the sensing circuit comprising:
   a parametric frequency comb generator including:
      a parametric oscillator;
         an electromechanical resonator coupled to the parametric oscillator;
      an input for receiving a pump signal; and
      an output for transmitting a frequency comb, the output either combined with or separate from the input,
      wherein the parametric frequency comb generator produces the frequency comb centered around an input frequency of the pump signal received by the input, a multiple of the input frequency, or a fraction of the input frequency,
      wherein a line spacing of the frequency comb is a function of the input frequency, a power of the pump signal received by the parametric frequency comb generator, a resonance frequency of the resonator, or combinations thereof; and
      at least one sensing element sensitive to the parameter of interest and coupled to the parametric frequency comb generator, wherein a presence, absence, or change of the parameter of interest alters the line spacing of the frequency comb produced by the parametric frequency comb generator;
   detecting, by the sensing element, the presence, absence, or change of the parameter of interest;
   receiving, at the sensing circuit, the pump signal having the input frequency;
   outputting, via the sensing circuit, the frequency comb having the altered line spacing; and
   determining, from the altered line spacing, the detected presence, absence, or change of the parameter of interest.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A is an illustration of a schematic representation and board-image of the Pierce oscillator. The typical output spectrum for a Pierce oscillator circuit is shown, demonstrating the continuous wave (CW)/frequency-comb output for the Pierce oscillator.

FIG. 1B is an illustration of a schematic representation and board-image of the Parametric Frequency Comb Generator (PFCG) circuit built in accordance with the methods and techniques described herein. The output spectrum for the PFCG circuit is shown, demonstrating the CW/frequency-comb output for the PFCG circuit.

FIG. 2A illustrates a process flow for microfabrication of an Aluminum Scandium Nitride (AlScN) microacoustic resonant infrared (IR) detector (“AlScN IR detector”) in accordance with various embodiments.

FIG. 2B illustrates a top view of the fabricated AlScN IR detector of FIG. 2A.

FIG. 2C illustrates a top view Scanning Electron Microscope (SEM) image of a prototype AlScN IR detector in accordance with various embodiments.

FIG. 3 illustrates measured phase noise levels for the PFCG circuit at three different frequency offsets (e.g., 0.1, 1, and 10 kHz) when sweeping the PFCG's input power at 246 MHz. Operating points “A” and “B” are identified. Point “B” shows the best phase-noise, at a cost of being more sensitive to random amplitude variations in the input power levels. Point “A” leads to a worse performance than Point “B” but shows full immunity to stochastic fluctuations in the pump power drive.

FIG. 4 illustrates a measured phase noise for the Pierce oscillator (in blue) and for the PFCG when operating at point A and point B (in green and red, respectively). The PFCG's input power is 14 mW, while the output power of the strongest tone is 10 μW. The DC power consumption of the loop oscillator is 100 mW, while the output power is 0.4 mW.

FIG. 5 illustrates an experimental setup used to detect IR-induced frequency shifts for both PFCG and Pierce oscillator. A collimated quantum cascade laser (QCL) and a red pointer are first aligned along the same optical axis, then combined through a right-angle reflective prism, and finally pointed together towards the IR AlScN detector. The IR-induced frequency shift is measured by connecting the read-out circuit to a spectrum analyzer.

FIG. 6 illustrates a measured frequency shift for both the PFCG and Pierce oscillator when switching the IR laser from “OFF” to “ON.” In the “ON” state the IR power absorbed by the resonator is estimated to be 10.7 μW. The evidence shows that the PFCG has a higher sensitivity than the Pierce oscillator.

FIG. 7 illustrates a graph of measured LoD for both the PFCG operating at point “A” and the Pierce loop oscillator. The PFCG shows a one-fold improvement in the best achievable LoD, and two orders of magnitude improvements at key integration times for IR cameras with 10-to-1000 Hz refresh rates, such as those rates used for aerial thermography, surveillance, etc.

FIG. 8 illustrates a PFCG circuit formed by a set of lumped inductors, capacitors, a varactor diode, an acoustic resonator, and a single antenna.

FIG. 9A illustrates an experimental setup that utilizes a signal generator to generate an interrogating single tone signal at frequency (fᵢₙ) while the tag's response is readout through a spectrum analyzer that is connected to an antenna with center frequency around fᵢₙ. The tag responds with a passively generated frequency comb lines centered around fᵢₙ with comb line spacing equal to Δf.

FIG. 9B illustrates a measured comb response of the tag when it was interrogated with a frequency at 836 MHZ.

FIG. 10 illustrates the comb line spacing (Δf) that may be intrinsically controlled by changing the resonator's coupling coefficient

$$( {k}_{t}^{2} ) .$$

The relationship between

$${k}_{t}^{2}$$

and Δf is directly proportional, where increasing or decreasing the

$${k}_{t}^{2}$$

value results in an increase or decrease in the comb line spacing value Δf.

FIGS. 11A and 11B illustrate a quasi-harmonic tag (qHT), or frequency comb-based radio frequency identification (RFID) tag, supplied with an input frequency (fᵢₙ), which activates the generation of a multitude of output frequencies Nfᵢₙ+nΔf, where N refers to the multiples of the interrogation frequency (N=½, 1, 2, 3, . . . N) and n refers to multiples of the spacing Δf (n=1, 2, 3, . . . n). Such Nfᵢₙ+nΔf outputs may be driven in systems with many numbers of antennas. This illustration depicts the cases where only one or two antennas are used to create the qHT.

FIGS. 12A and 12B illustrate a qHT circuit relying on two antennas. To synthesize a qHT, requires a parametric oscillator (PO) coupled with a resonator (Res.). Coupling interactions between these elements generate the modulations of the output signal. At either the input or output of the qHT, a parameter-of-interest (PoI)-sensitive component or a matching network is embedded.

FIG. 13 illustrates POs comprised of several meshes which satisfy sets of resonance conditions that maximize the voltage modulation across the nonlinear circuit element. In the case of a PO with two ports, three circuit branches are used to satisfy four circuital mesh conditions. The conditions are as follows: Z₁ and Z₃ series resonate fᵢₙ, while Z₁ parallel resonates fᵢₙ/2. Similarly, Z₃ and Z₂ series resonate fᵢₙ/2, while Z₂ parallel resonates fᵢₙ.

FIG. 14 illustrates POs comprised of several meshes which satisfy sets of resonance conditions that maximize the voltage modulation across the nonlinear circuit element. In the case of a PO with one port, three circuit branches are used to satisfy several circuital mesh conditions. The conditions are as follows: Z₁ and Z₃ must series resonate fin, while Z₁ and Z₂ must series resonate fᵢₙ/2.

### DETAILED DESCRIPTION OF THE INVENTION

The methods and techniques described herein present circuits, referred to herein as Parametric Frequency Comb Generators (PFCG), for piezoelectric (e.g., AlScN as shown and described herein) electromechanically resonant sensors and tags. The PFCG may generally include an RF parametric oscillator (PO) coupled with an electromechanical resonator.

Such PFCG provide a class of passive devices that may be driven by an input frequency and are configured to respond with a multitude of other frequencies, with those frequencies either centered around or at fraction and multiples of the input frequency. Devices incorporated with a PFCG may be constructed using discrete components, on-chip components, and/or a heterogeneous mixture of electrical components. Such PFCG devices generally include a combination input/output (I/O) and/or separate input and output. Such inputs, outputs, and I/Os can generally be provided as ports, antennas, and/or hardwired connections.

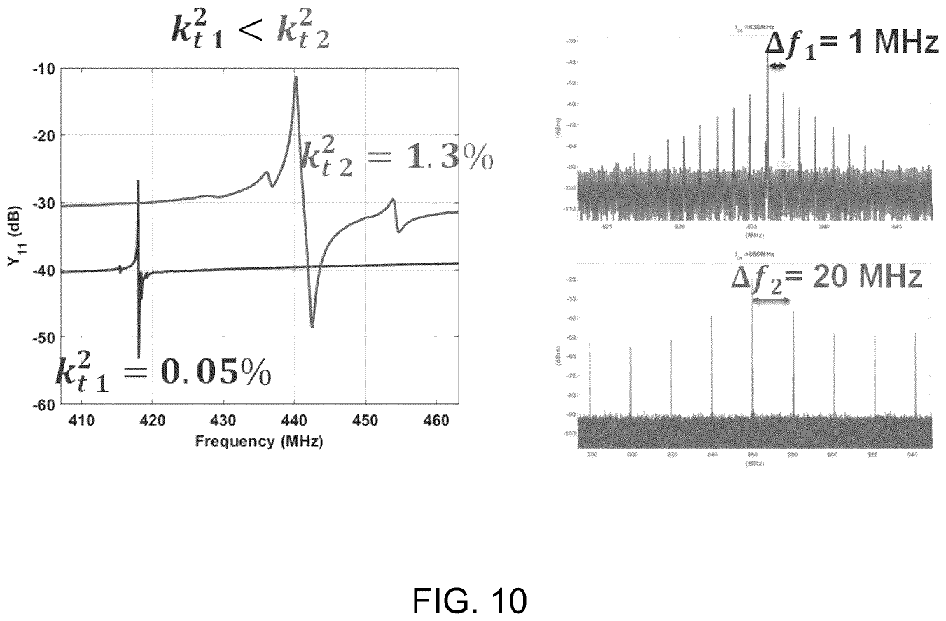

The spacing of the generated signals can be controlled by the power received by the device incorporating the PFCG. That is, a PFCG incorporated device can use the electromechanical coupling between the mechanical resonator and the electrical parametric oscillator to generate power dependent modulations of the oscillator's waveforms. Thus, by embedding a sensing element with an electrical readout, the modulation spacing of the generated frequency comb in response to a parameter of interest can be changed to implement wireless sensing. Additionally, the spacing of the generated signals may be controlled through parameters of interest which alter the device's fingerprint. For example, FIG. 10 illustrates how the comb line spacing (Δf) of an output response from a PFCG incorporated tag can be intrinsically controlled by changing the resonator's coupling coefficient

$$( {k}_{t}^{2} ) .$$

In particular, FIG. 10 illustrates that the relationship between

$${k}_{t}^{2}$$

and Δf is directly proportional, where increasing or decreasing the

$${k}_{t}^{2}$$

value results in an increase or decrease in the comb line spacing value Δf.

As shown through experimentation, such PFCG circuits make it possible to generate self-sustained oscillation states set by the resonance frequency of an electromechanical resonator without requiring active components, while consuming ~10 mW, and while limiting the radio frequency (RF) power dissipated by the device to less than 1 μW. The PFCG is differentiated from conventional POs, where increasing the power of the input pump signal beyond a certain threshold (Pₜₕ) triggers a subharmonic oscillation phase-locked to the pump signal. Instead, when the PFCG is driven beyond threshold it enters a pre-synchronization regime. In this regime, the PFCG generates a frequency comb centered around half of the pump signal's frequency (fᵢₙ), with a line spacing set by the difference between the resonance frequency of the electromechanical resonator and fᵢₙ/2. Alternatively, in some embodiments, the PFCG can generate a frequency comb centered around the pump signal's frequency (fᵢₙ), with a line spacing set by the difference between the resonance frequency of the electromechanical resonator and fᵢₙ. Even more generally, the frequency comb can be centered on any multiple or fraction of fᵢₙ. As such, the PFCG frequency comb output can most broadly be characterized as Nfᵢₙ+nΔf, where N refers to a multiple of the interrogation frequency (N=½, 1, 2, 3, . . . N) and n refers to multiples of the spacing Δf (n=1, 2, 3, . . . n).

Put succinctly, previous technology using subharmonic tags (SubHTs) may have an output response which is generated at half the input frequency. The PFCG described herein differs from the SubHTs as the PFCG may generate the output response in a comb format centered around the input frequency or multiples or fractions thereof.

Although generally described herein and prototyped as using AlScN resonators, electromechanical resonators constructed from any suitable piezoelectric material can be used in accordance with various embodiments, including, for example, AlScN, lithium niobate (LiNbO₃, hereinafter LN), aluminum chromium nitride (AlCrN), lead zirconate titanate (PZT), lithium tantalate (LiTaO₃), gallium nitride (GaN), aluminum nitride (AlN), any other suitable piezoelectric material, or combinations thereof. In addition, although prototyped as MEMS resonators, the resonators can also be formed into or onto any other suitable structure. In various embodiments, for example, the resonators can be built directly on a silicon wafer in an array or built/configured in any other suitable arrangement on (or in) any other suitable structure.

### PFCG-Based IR Detectors

In some embodiments, the PFCG provides a sensing system for piezoelectric (e.g., AlScN as shown and described herein) microacoustic resonant infrared [1] detectors (“AlScN IR detectors”). As noted above, although described herein and prototyped as using AlScN IR detectors, microacoustic resonant IR detectors constructed from any suitable piezoelectric material can be used in accordance with various embodiments, including, for example, AlScN, LN, AlCrN, PZT, LiTaO₃, GaN, AlN, any other suitable piezoelectric material, or combinations thereof and, although prototyped as MEMS resonators, the resonators can also be formed into or onto any other suitable structure. In various embodiments, for example, the resonators can be built directly on a silicon wafer in an array or built/configured in any other suitable arrangement on (or in) any other suitable structure.

The PFCG makes it possible to generate self-sustained oscillation states set by the resonance frequency of a 120 MHz AlScN IR detector without requiring active components, while consuming ~10 mW and while limiting the radio frequency (RF) power dissipated by the AlScN device to less than 1 μW. In the prototype PFCG AlScN IR detector, when the PFCG is driven beyond threshold it enters a pre-synchronization regime wherein the frequency comb is centered around half of the pump signal's frequency (fᵢₙ), with a line spacing set by the difference between the resonance frequency of the AlScN device and fᵢₙ/2.

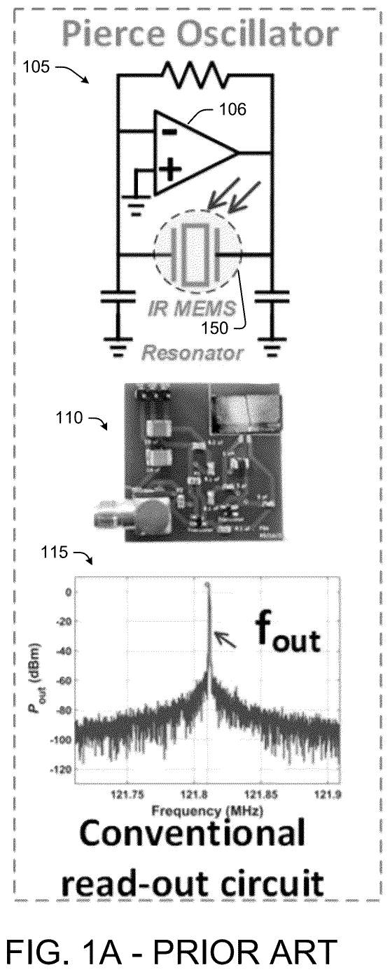

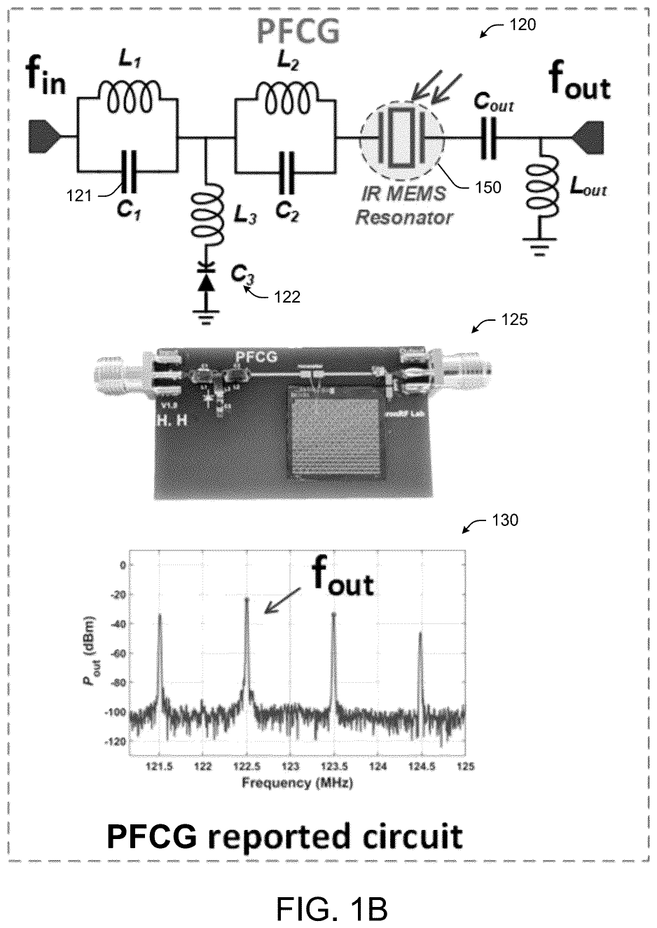

FIG. 1A illustrates a Pierce oscillator circuit 100, a board-image 110 of the Pierce oscillator circuit 100, and a typical output spectrum 115 for the Pierce oscillator circuit, demonstrating the CW/frequency-comb output (readout) for the Pierce oscillator circuit 100. FIG. 1B illustrates a PFCG circuit 120, a board-image of a prototype 125 of the PFCG circuit built in accordance with the methods and techniques described herein, and a typical output spectrum 130 for the PFCG circuit 120, demonstrating the CW/frequency-comb output (readout) for the PFCG circuit 120.

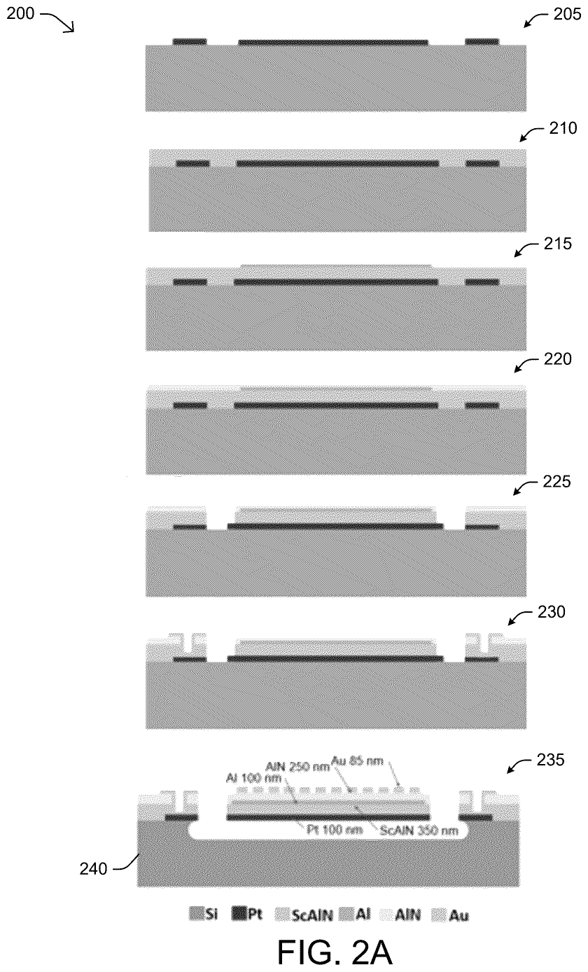

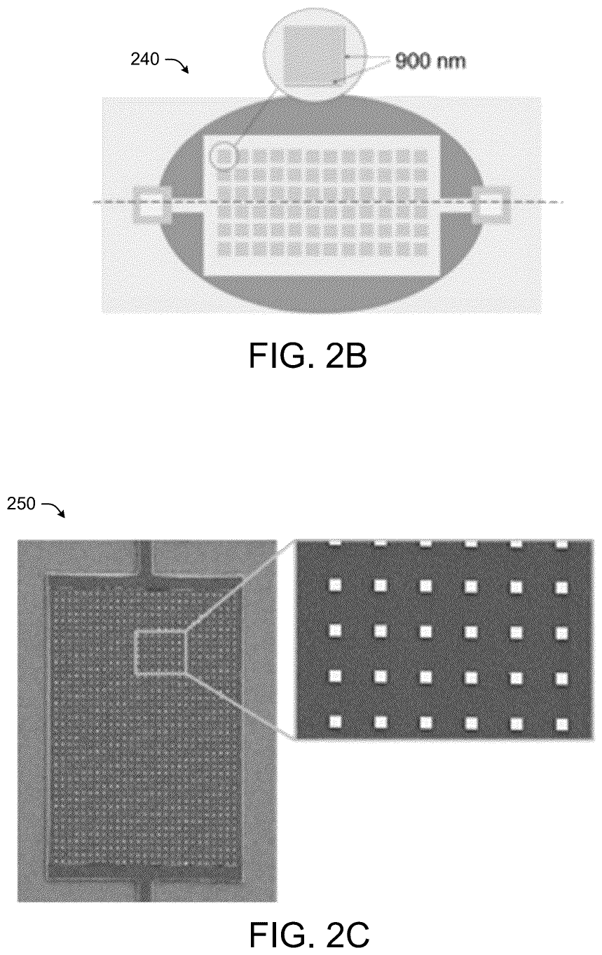

Referring now to FIGS. 1A, 1B, and 3-7, the improvements realized by the PFCG circuit can be demonstrated by comparison to conventional read-out schemes, such as the typical output spectrum 115 for a Pierce oscillator readout shown in FIG. 1A. For the comparison, two read-out circuits, specifically, the Pierce oscillator circuit 100 depicted in the circuit diagram and board-image 110 of the Pierce oscillator of FIG. 1A and in the PFCG circuit 120 depicted in the circuit diagram and board-image 125 of FIG. 1B, were assembled on separate printed-circuit-boards. The comparison used two copies of the same AlScN IR detector 150, which were manufactured according to the exemplary process flow described in connection with FIG. 2A below. The Pierce oscillator circuit 100 included a Pierce oscillator 105 using a bipolar junction transistor 106. The PFCG circuit 120 included a PFCG 121 using an off-the-shelf varactor 122 as a nonlinear reactance.

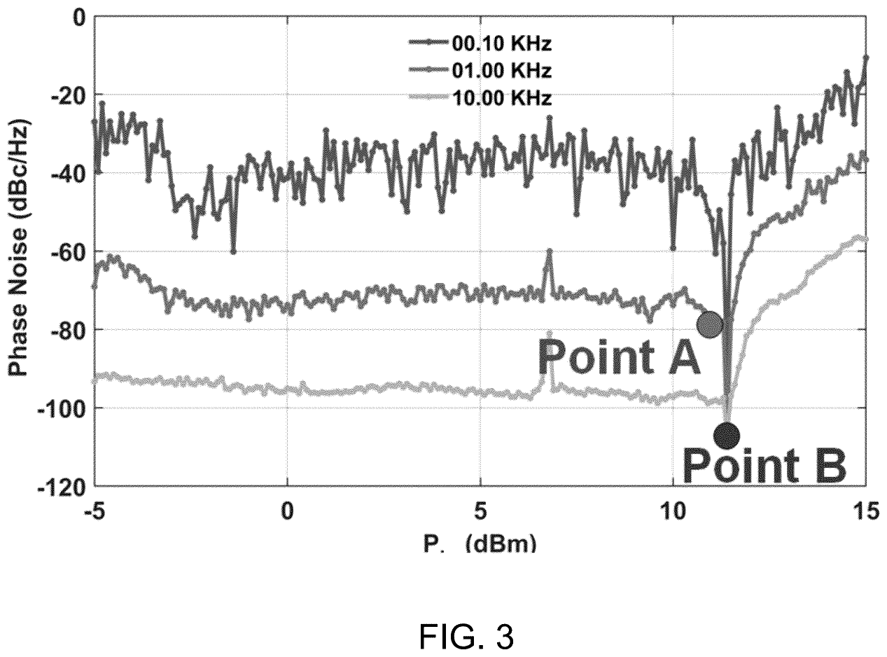

FIG. 3 illustrates a graph showing the PFCG circuit's measured phase noise levels at three different frequency offsets (e.g., 0.1, 1, and 10 kHz) when sweeping the PFCG's input power at 246 M Hz. As shown in FIG. 3, the PFCG's phase-noise at 100 Hz/1 kHz/10 kHz offsets from the strongest comb line's frequency (fₒᵤₜ) was measured for varying pump power levels, proving the existence of a region of operation, operating points “A” and “B”. As shown, point “B” shows the best phase-noise, at a cost of being more sensitive to random amplitude variations in the input power levels. Point “A” leads to a worse performance than Point “B” but shows full immunity to stochastic fluctuations in the pump power drive.

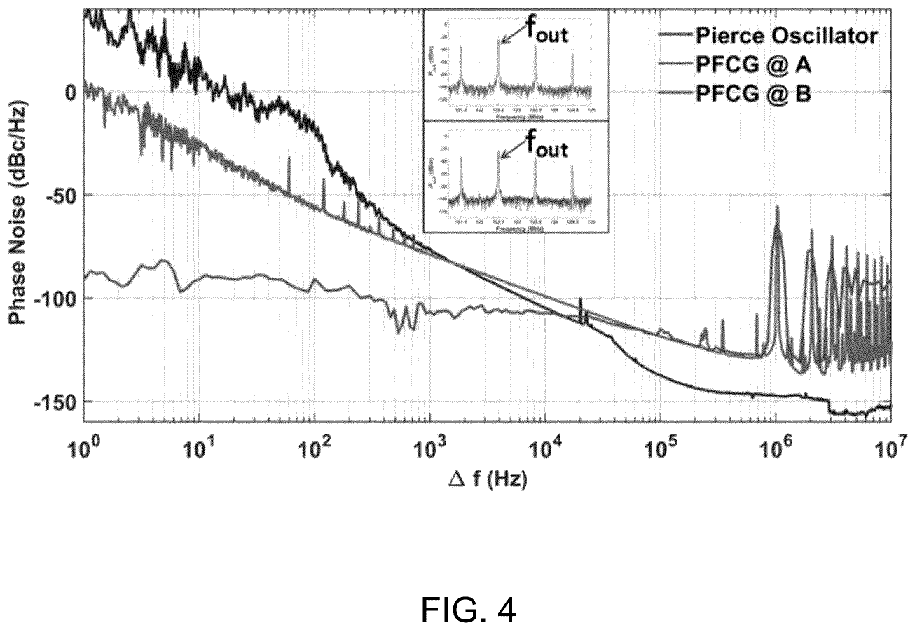

FIG. 4 is a graph of a measured phase noise for the Pierce oscillator 100 (in blue) and for the PFCG 120 when operating at point A and point B (in green and red, respectively), as shown in FIG. 3. The PFCG's input power is 14 mW, while the output power of the strongest tone (e.g., the principle comb-line) is 10 μW. By contrast, the direct current (DC) power consumption of the Pierce loop oscillator is 100 mW, while the output power of the oscillation tone is 0.4 mW. Thus, FIG. 4 illustrates highly improved long-term stability of the PFCG with respect to the Pierce oscillator.

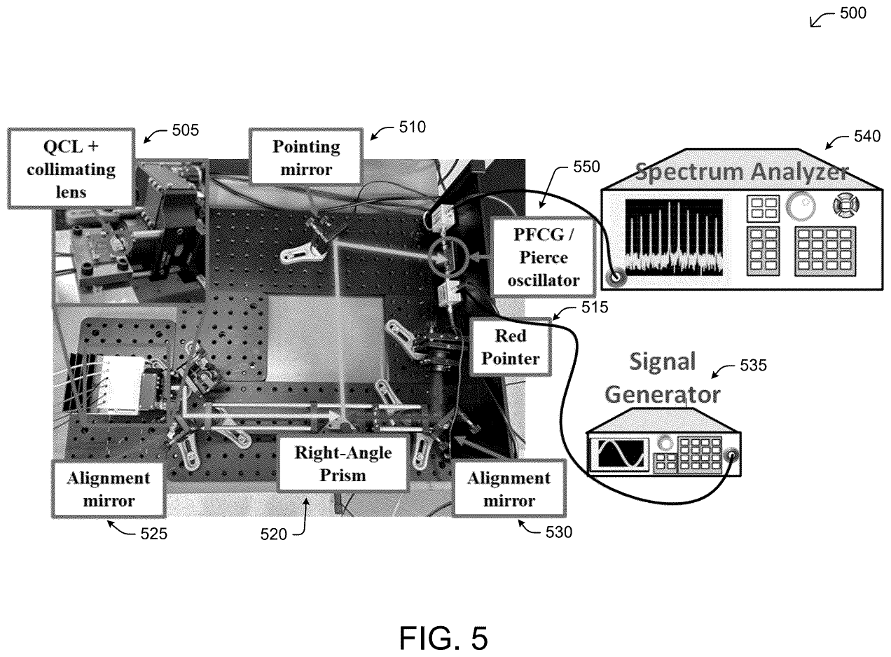

FIG. 5 illustrates an experimental setup 500 used to detect IR-induced frequency shifts for both the PFCG circuit 120 and the Pierce oscillator circuit 100. The experimental setup comprises a collimated quantum cascade laser (QCL) 505, a pointing mirror 510, a red pointer 515, a right-angle reflective prism 520, and alignment mirrors 525, 530. To detect IR-induced frequency shifts using the experimental setup, the QCL 505 and the red pointer 515 are first aligned along the same optical axis, such as by using alignment mirrors 525, 530. The QCL 505 and the red pointer 515 are then combined through a right-angle reflective prism 520, and finally pointed together towards the IR AlScN detector, via the pointing mirror 510. The IR-induced frequency shift is measured by connecting the read-out circuit 550 (the PFCG circuit 120 or Pierce oscillator circuit 100 under test) to a spectrum analyzer 540.

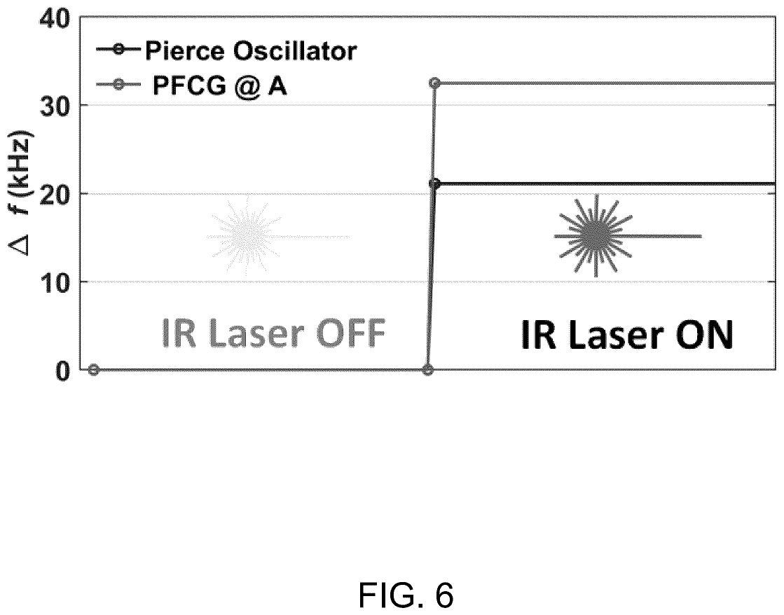

FIG. 6 illustrates a measured frequency shift for both the PFCG and Pierce oscillator when switching the IR laser from “OFF” to “ON” (e.g., ON/OFF modulation). In experimentation, such as using the experimental setup illustrated in FIG. 5, the sensitivity of both assembled circuits (e.g., Pierce oscillator, PFCG) to IR was characterized by using an ON/OFF modulation of a 4.53 μm laser source. The PFCG was configured to operate at Point A. From these measurements, an average sensitivity to IR was extracted (S=Δf/fₒᵤₜ, being Δf the IR-induced frequency shift of fₒᵤₜ for both circuits). In the “ON” state the IR power absorbed by the resonator is estimated to be 10.7 μW. The evidence showed that the PFCG has a higher sensitivity than the Pierce oscillator.

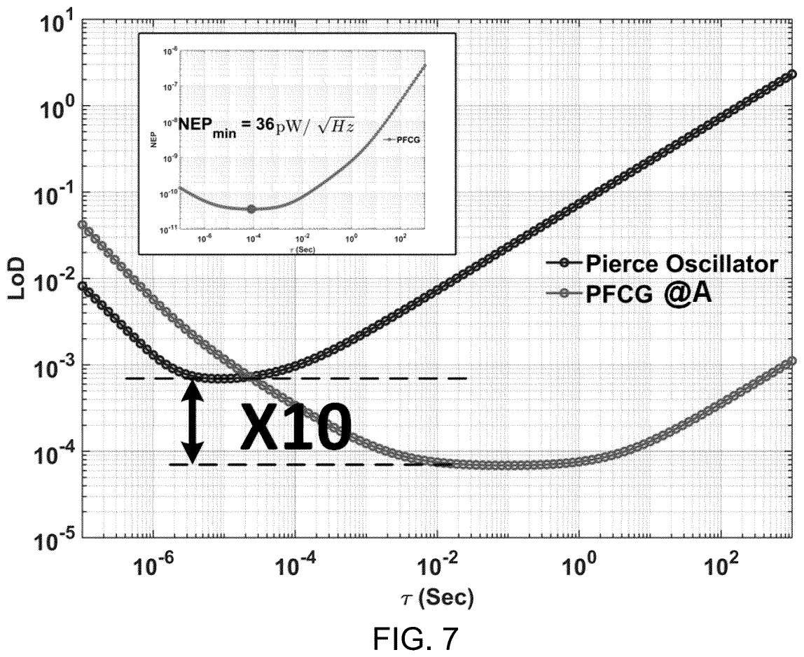

FIG. 7 illustrates a graph of measured limit-of-detection (LoD) for both the PFCG operating at point “A” and the Pierce oscillator. From the extracted S-values and phase-noise performance of both circuits, the LoD was computed as S/σ_{ν} (τ), where σ_{ν} is the Allan deviation (i.e., Δfₙ/fₒᵤₜ) at different integration times (τ) attained. The PFCG showed an up-to-10× improvement in the best achievable LoD with respect to the Pierce-oscillator and a minimum Noise Equivalent Power of 36 pW/\sqrt{Hz} at 0.1 msec, while consuming (~15 mW) nearly one-fold less power and while limiting the RF power absorbed by the resonator to less than 360 nW. Even higher performance is expected from the PFCG when it operates at Point B. The PFCG showed a one-fold improvement in the best achievable LoD, and two orders of magnitude improvements at key integration times for IR cameras with 10-to-1000 Hz refresh rates, such as those rates used for aerial thermography, surveillance, etc.

An exemplary process flow 200 for microfabrication of an Aluminum Scandium Nitride (AlScN) microacoustic resonant infrared (IR) detector (“AlScN IR detector”) 240 is shown in FIG. 2A. In step 205, a sputtering and lift-off of Pt electrodes is performed. Then, in step 210 aluminum scandium nitride (AlScN) is a sputtered over the Pt electrodes. As shown in step 215, aluminum (Al) plate is then patterned and sputtered onto a portion of the AlScN. At step 220, aluminum nitride (AlN) is then sputtered over the Al plate and AlScN. Then, as shown in step 225 release pits are formed via an AlN dry etch. In step 230 vias are etched followed by gold (Au) deposition to plate the vias and, as better shown in connection with step 235, to form contact pads over the AlN of the resonant structures between the release pits. Finally, at step 235, further etching is performed to suspend the resonant structures, thereby permitting the resonant structures to vibrate and deform when responsively driven by a signal. It should be noted, however, that any suitable process and/or materials can be used to form an AlScN IR detector in accordance with various embodiments.

An illustration of the cross-section of the fully released AlScN IR detector 240 is provided at step 235 of FIG. 2A and a top view illustration of the AlScN IR detector 240 is provided in FIG. 2B. As shown in FIGS. 2A and 2B, the Pt structures of the AlScN IR detector 240 are 100 nm thick, the ScA IN structures are 350 nm thick, the Al plate is 100 nm thick, the A IN structures are 250 nm thick, and the gold pads are patterned and formed as a 12×6 array of 900 nm×900 nm squares having a thickness of 85 nm. However, it will be apparent to one of skill in the art that any combination of suitable materials and material layer thicknesses can be used in accordance with various embodiments. Furthermore, it will be apparent to one of skill in the art that any suitable number of pads, formed on the resonant structures in any suitable pattern or arrangement, and individually having any suitable size, shape, and/or thickness, can be used in accordance with various embodiments.

FIG. 2C shows a top view Scanning Electron Microscope (SEM) image 250 of a fabricated prototype AlScN IR detector. As shown in FIG. 2C, that prototype AlScN IR detector included a 27×40 array of pads patterned on the resonant structures thereof.

### PFCG-Based Passive Tags

In some embodiments, the PFCG provides one or more passive tags such as, for example, passive RFID tags. As noted above, although described herein and prototyped as using AlScN electromechanical resonators, resonators constructed from any suitable piezoelectric material can be used in accordance with various embodiments, including, for example, AlScN, LN, AlCrN, PZT, LiTaO₃, GaN, AlN, any other suitable piezoelectric material, or combinations thereof and, although prototyped as MEMS resonators, the resonators can also be formed into or onto any other suitable structure. In various embodiments, for example, the resonators can be built directly on a silicon wafer in an array or built/configured in any other suitable arrangement on (or in) any other suitable structure.

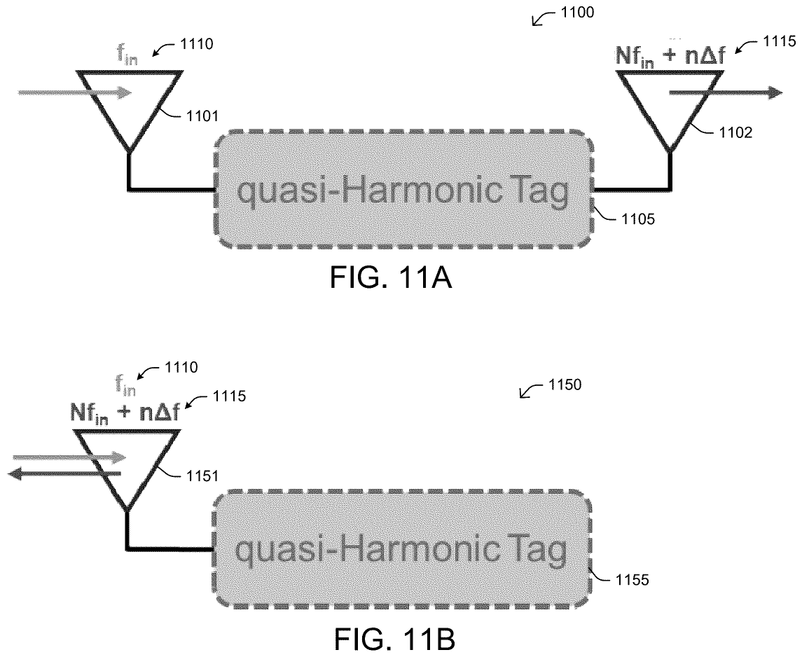

FIG. 11A illustrates a two-antenna passive tag 1100 having an input antenna 1101 for receiving an input signal having an input frequency (fᵢₙ) 1110, which activates a quasi-harmonic tag (qHT) 1105 coupled to the input antenna 1101, resulting the generation of a multitude of output frequencies (Nfᵢₙ+nΔf) 1115, where N refers to the multiples of the interrogation frequency (N=½, 1, 2, 3, . . . N) and n refers to multiples of the spacing Δf (n=1, 2, 3, . . . n). Such Nfᵢₙ+nΔf output frequencies 1115 can be transmitted by an output antenna 1102 coupled to the qHT 1105 in accordance with some embodiments.

FIG. 11B illustrates a single antenna passive tag 1150 having a combined input/output antenna 1151 for receiving an input signal having an input frequency (fᵢₙ) 1110, which activates a quasi-harmonic tag (qHT) 1155 coupled to the input/output antenna 1151, resulting the generation of a multitude of output frequencies (Nfᵢₙ+nΔf) 1115, where N refers to the multiples of the interrogation frequency (N=½, 1, 2, 3, . . . N) and n refers to multiples of the spacing Δf (n=1, 2, 3, . . . n). Such Nfᵢₙ+nΔf output frequencies 1115 can then be transmitted by the input/output antenna 1151 in accordance with some embodiments.

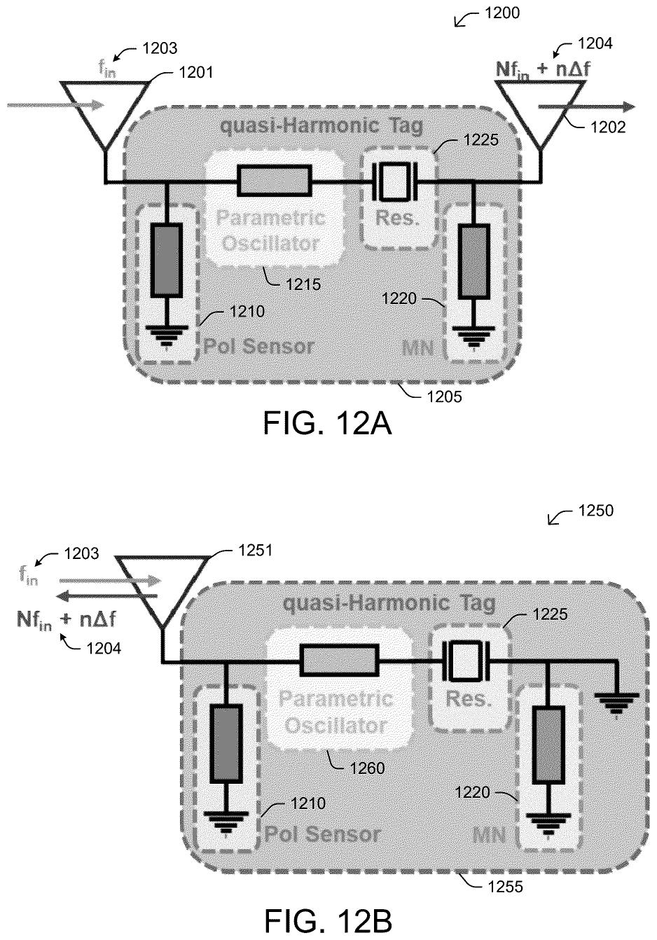

FIG. 12A illustrates a two-antenna parameter-of-interest (Pol) sensitive passive tag 1200 having an input antenna 1201 for receiving an input signal having an input frequency (fᵢₙ) 1203, which activates a POI sensitive qHT 1205 coupled to the input antenna 1201, resulting the generation of a multitude of output frequencies (Nfᵢₙ+nΔf) 1204, where N refers to the multiples of the interrogation frequency (N=½, 1, 2, 3, . . . N) and n refers to multiples of the spacing Δf (n=1, 2, 3, . . . n). The POI sensitive qHT 1205 includes a parametric oscillator (PO) 1215 that is coupled with a resonator 1225. The coupling interactions between the PO 1215 and the resonator 1225 generate the modulations of the output signal 1204. Those modulations of the output signal are also modifiable by characteristics of, for example, a POI sensitive element 1210 and/or a matching network 1220 coupled at either the input or the output of the POI sensitive qHT 1205. In such POI sensitive qHTs 1205, the characteristics of the POI sensitive element 1210 and/or the matching network 1220 can change depending on electrical and/or POI conditions, thereby modifying the modulated Nfᵢₙ+nΔf output frequencies 1204. The modified, modulated Nfᵢₙ+nΔf output frequencies 1204 can be transmitted by an output antenna 1202 coupled to the POI sensitive qHT 1205 in accordance with some embodiments.

FIG. 12B illustrates a single antenna POI sensitive passive tag 1200 having a combined input/output antenna 1251 for receiving an input signal having an input frequency (fᵢₙ) 1203, which activates a POI sensitive qHT 1255 coupled to the input/output antenna 1251, resulting in the generation of a multitude of output frequencies (Nfᵢₙ+nΔf) 1204, where N refers to the multiples of the interrogation frequency (N=½, 1, 2, 3, . . . N) and n refers to multiples of the spacing Δf (n=1, 2, 3, . . . n). The POI sensitive qHT 1255 includes a parametric oscillator (PO) 1260 that is coupled with a resonator 1225. The coupling interactions between the PO 1260 and the resonator 1225 generate the modulations of the output signal 1204. Those modulations of the output signal are also modifiable by characteristics of, for example, a POI sensitive element 1210 and/or a matching network 1220 coupled at either the input or the output of the POI sensitive qHT 1255. In such POI sensitive qHTs 1255, the characteristics of the POI sensitive element 1210 and/or the matching network 1220 can change depending on electrical and/or POI conditions, thereby modifying the modulated Nfᵢₙ+nΔf output frequencies 1204. The modified, modulated Nfᵢₙ+nΔf output frequencies 1204 can be transmitted by the input/output antenna 1251 in accordance with some embodiments.

Although FIGS. 11A, 11B, 12A, and 12B are discussed hereinabove in the context of passive PFCG tags having one or more antennas for receiving the input signal and transmitting the output signal, it is to be understood that such configurations are also suitable and appropriate for use in connection with devices and/or circuits having wired connections such as input ports, output ports, I/O ports, and/or hardwired inputs and/or outputs. Furthermore, it is contemplated that PFCG devices and/or circuits can include both one or more wired connections and one or more antennas.

Furthermore, although FIGS. 12A and 12B include one or more POI sensitive elements 1210 and/or matching networks 1220 integrated within their respective qHTs 1205, 1255, it will be apparent in view of this disclosure that such sensitive elements 1210 and/or matching networks 1220 can, in some embodiments, be separate devices or circuits coupled to the qHT.

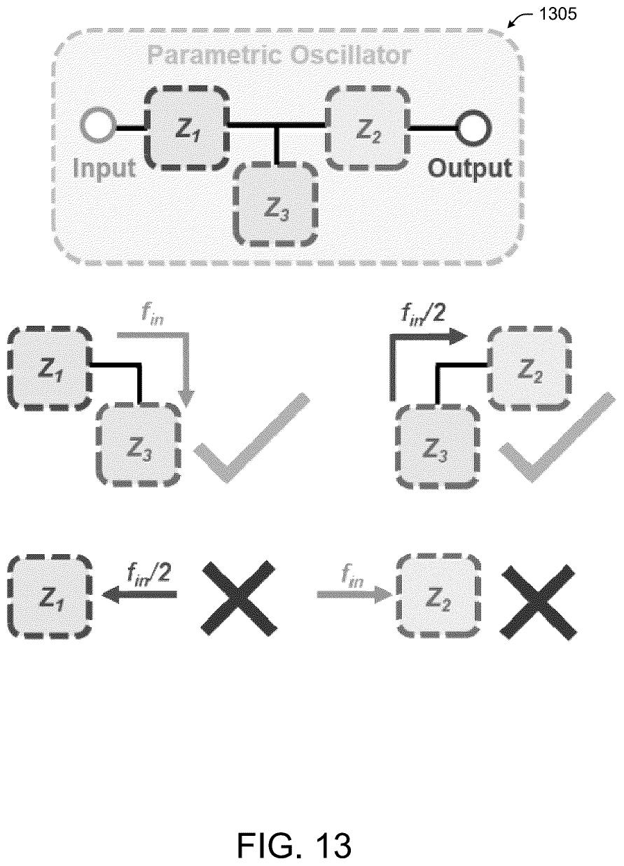

FIG. 13 illustrates a PO 1305 comprised of several meshes which satisfy sets of resonance conditions that may maximize the voltage modulation across the nonlinear circuit element, in accordance with some embodiments wherein the PO 1305 has two ports. In such embodiments, three circuit branches may be used to satisfy four circuital mesh conditions. In particular, Z₁ and Z₃ series resonate fᵢₙ, while Z₁ parallel resonates fᵢₙ/2 and, similarly, Z₃ and Z₂ series resonate fᵢₙ/2, while Z₂ parallel resonates fᵢₙ.

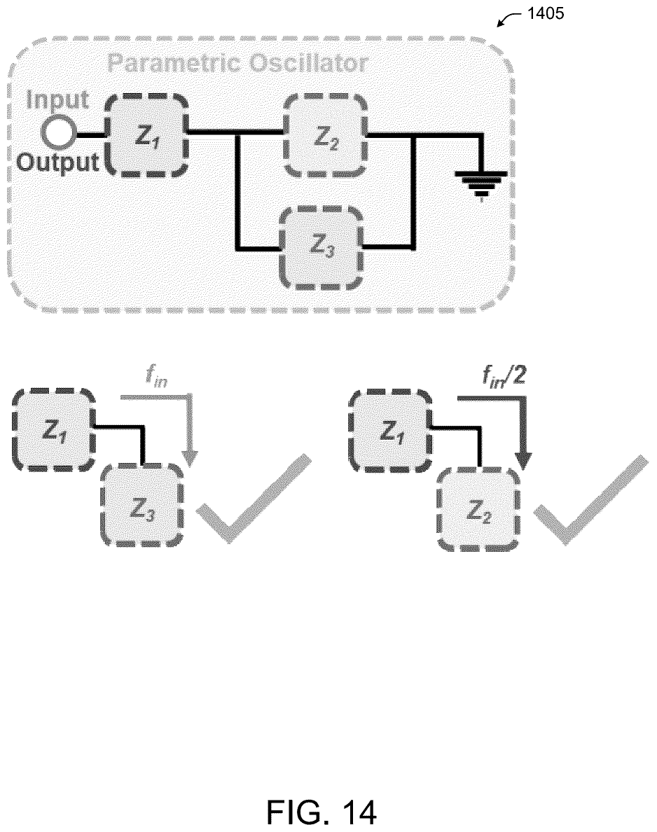

FIG. 14 illustrates a PO 1405 comprised of several meshes which satisfy sets of resonance conditions that may maximize the voltage modulation across the nonlinear circuit element, in accordance with some embodiments wherein the PO 1405 has one port. In such embodiments, three circuit branches may be used to satisfy two circuital mesh conditions. In particular, Z₁ and Z₃ must series resonate fin, while Z₁ and Z₂must series resonate f_{in/}2.

### Prototype PFCG Passive Tag

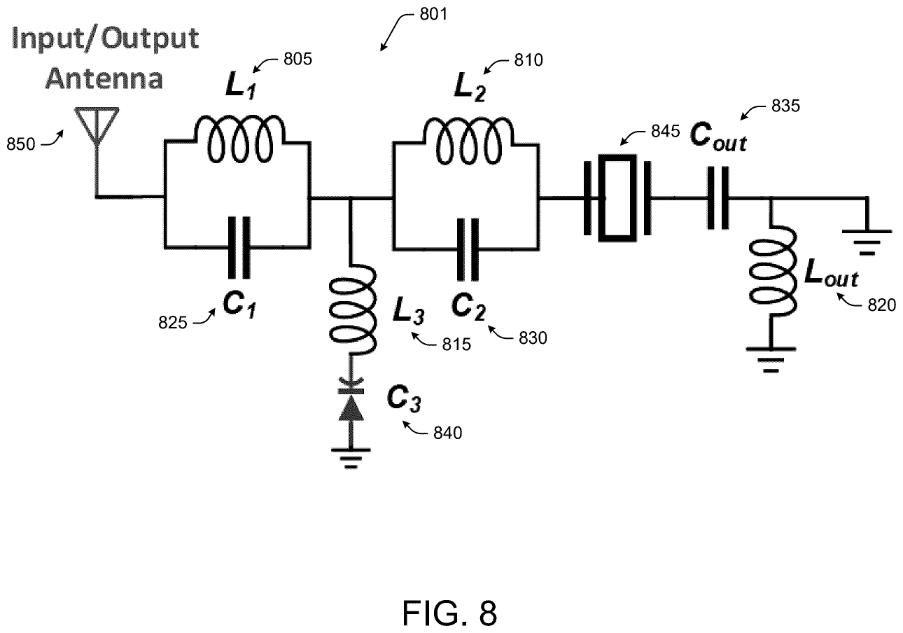

FIG. 8 illustrates a single input/output antenna PFCG circuit 800 for embodiment as or incorporation into a passive tag in accordance with some embodiments. The PFCG circuit 800 is comprised of a parametric oscillator 801 including a set of lumped inductors L₁ 805, L₂ 810, L3 815 and capacitors C₁ 825, C₂ 830 as well as a varactor diode 840. The parametric oscillator 801 is coupled to an electromechanical resonator 845, forming the basic PFCG architecture, which is further coupled to a matching network including a lumped inductor L_{OUT} 820 and capacitor C_{OUT} 835, and a single input/output antenna 850 to form the PFCG circuit 800.

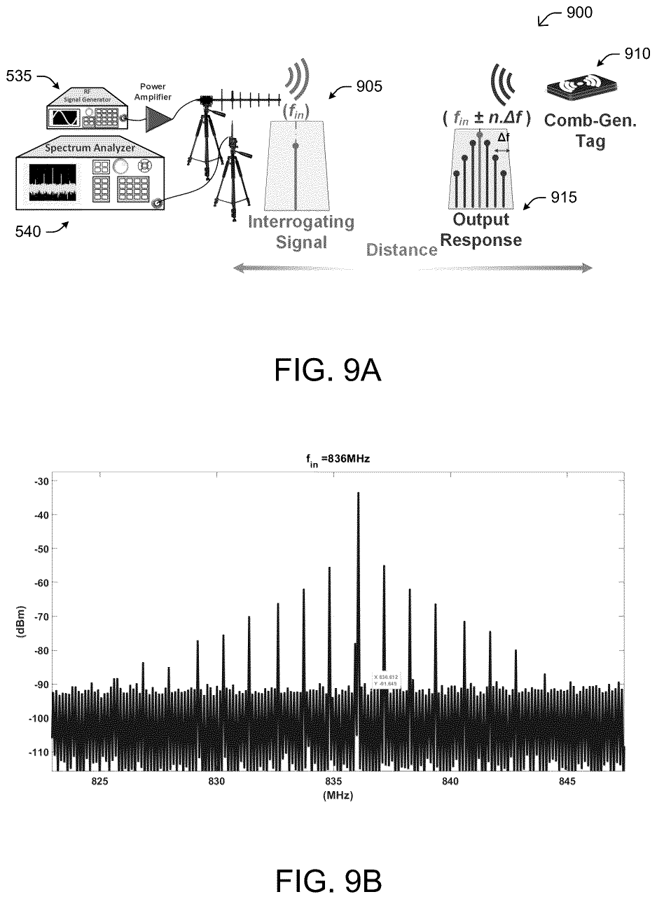

FIG. 9A illustrates an experimental setup 900 used for testing a response of a prototype passive tag 910 having the PFCG circuit 800 incorporated therein. The experimental setup 900 employs a signal generator 535 to generate an interrogating single tone signal 905 at frequency (fᵢₙ). The tag 910 may receive the interrogating single tone signal 905 and respond with an output response 915 of passively generated frequency comb lines centered around fin with comb line spacing equal to Δf, characterized as fᵢₙ±nΔf, where n refers to multiples of the spacing Δf (n=1, 2, 3, . . . n). In the experimental setup 900, a readout of the tag's output response 915 was provided via a spectrum analyzer 540 connected to an antenna with center frequency around fᵢₙ. FIG. 9B illustrates a measured comb response 915 of the prototype passive tag 910 when interrogated with an input frequency of 836 MHz.

### Advantages

The methods and techniques described herein for the PFCG have advantages over previous technologies, including, for example, at least the following:
First, the PFCG technology avoids self-interference because the PFCG generates frequencies that are different from its interrogation frequency, thus immunizing PFCGs to self-interference.
Second, PFCG technology is fully passive (i.e., does not require batteries or other power sources) while preserving low power thresholds and an extended (long) range due to unique parametric characteristics of the PFCG.
Third, devices and circuits incorporating PFCGs can include elements sensitive to various parameters of interest (POI), such as one or more of a physical parameter, an electrical parameter, a chemical agent, a biological agent, or combinations thereof. Multiple types of sensors of different POIs that possess an electrical readout may be integrated with a PFCG device for the implementation of wireless sensing. These multiple types of sensors may include sensors configured to detect a change in vibration frequency, a change in vibration intensity, a change in temperature, a change in humidity, a change in radiation concentration, a change in radiation energy, a change in radiation intensity, a change in radiation type, a change in acoustic frequency, a change in acoustic intensity, a change in acoustic power, a change in acoustic phase, a change in photonic intensity, a change in photonic frequency, a change in photonic phase, a change in photonic polarization, a change in a change in voltage of an electrical signal, a change in current of an electrical signal, a change in power of an electrical signal, a change in frequency of an electrical signal, a change in a magnetic field, an increase or decrease in a concentration of a chemical agent, a change in presence or absence of a chemical agent, an increase or decrease of a concentration of a biological agent, a change in presence or absence of a biological agent, or combinations thereof.
Fourth, the PFCG system or device may be implemented using either heterogeneous or monolithic integration of components resulting in a cost reduction and improved sensitivity. In a real-world application, the methods and techniques for a PFCG presented herein may either be applied for mass manufacturing in the millions, where there may be trade-offs between cost and performance, or for niche applications, in which case the costs may be less relevant, but superior performance is a priority.
Fifth, the PFCG system may provide improved immunity against clutter and multipath interference due to the use of different interrogation and read-out frequencies.

### Applications

This methods and technology for the PFCG described herein may be used to replace and/or enhance current RFID applications, such as localization, sensing, and target acquisition. The PFCG may be used for long-range passive RFID tags. Further, the methods and technology for the PFCG may be used for a variety of sensing applications, including environmental monitoring, structural monitoring, biological and health monitoring, as well as target tracking to object detection.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

### REFERENCES

“Plasmonic piezoelectric nanomechanical resonator for spectrally selective infrared sensing,” Y. Hui, J. S. Gomez-Diaz, Z. Qian, A. Alu and M. Rinaldi, Nature communications, (2016).

What is claimed is:

1. A parametric frequency comb generator comprising:
a parametric oscillator;
an electromechanical resonator coupled to the parametric oscillator;
an input for receiving a pump signal; and
an output for transmitting a frequency comb, the output either combined with or separate from the input,
wherein the parametric frequency comb generator produces the frequency comb centered around an input frequency of the pump signal received by the input, a multiple of the input frequency, or a fraction of the input frequency,
wherein a line spacing of the frequency comb is a function of the input frequency, a power of the pump signal received by the parametric frequency comb generator, a resonance frequency of the resonator, or combinations thereof.

2. The parametric frequency comb generator of claim 1, wherein the parametric oscillator comprises at least one non-linear element and at least one resonant circuit.

3. The parametric frequency comb generator of claim 2, wherein the at least one non-linear element includes one or more of a varactor, a diode, or a combination thereof.

4. The parametric frequency comb generator of claim 2, wherein the at least one resonant circuit includes an LC circuit.

5. The parametric frequency comb generator of claim 2, wherein the parametric oscillator includes a varactor arranged in a T-network structure with two LC circuits.

6. The parametric frequency comb generator of claim 1, wherein the input includes at least one of an input antenna or an input port and the output comprises at least one of a separate output antenna or a separate output port.

7. The parametric frequency comb generator of claim 1, wherein the input and output comprise at least one of a combination input/output antenna or a combination input/output port.

8. A sensing circuit for detection or measurement of a parameter of interest, the sensing circuit comprising:
a parametric frequency comb generator including:
a parametric oscillator;
an electromechanical resonator coupled to the parametric oscillator;
an input for receiving a pump signal; and
an output for transmitting a frequency comb, the output either combined with or separate from the input,
wherein the parametric frequency comb generator produces the frequency comb centered around an input frequency of the pump signal received by the input, a multiple of the input frequency, or a fraction of the input frequency,
wherein a line spacing of the frequency comb is a function of the input frequency, a power of the pump signal received by the parametric frequency comb generator, a resonance frequency of the electromechanical resonator, or combinations thereof; and
at least one sensing element sensitive to the parameter of interest and coupled to the parametric frequency comb generator, wherein a presence, absence, or change of the parameter of interest alters the line spacing of the frequency comb produced by the parametric frequency comb generator.

9. The sensing circuit of claim 8, wherein the at least one sensing element is sensitive to one or more of a physical parameter, an electrical parameter, a chemical agent, a biological agent, or combinations thereof.

10. The sensing circuit of claim 9, wherein the at least one sensing element is sensitive to a change in one or more of a change in vibration frequency, a change in vibration intensity, a change in temperature, a change in humidity, a change in radiation concentration, a change in radiation energy, a change in radiation intensity, a change in radiation type, a change in acoustic frequency, a change in acoustic intensity, a change in acoustic power, a change in acoustic phase, a change in photonic intensity, a change in photonic frequency, a change in photonic phase, a change in photonic polarization, a change in a change in voltage of an electrical signal, a change in current of an electrical signal, a change in power of an electrical signal, a change in frequency of an electrical signal, a change in a magnetic field, an increase or decrease in a concentration of a chemical agent, a change in presence or absence of a chemical agent, an increase or decrease of a concentration of a biological agent, a change in presence or absence of a biological agent, or combinations thereof.

11. The sensing circuit of claim 10, wherein the at least one sensing element is sensitive to a chemical agent selected from a gas, a toxin, a volatile organic compound, an atmospheric or water-born pollutant, a vehicle emission, an emission of an animal or human, soil moisture, a pharmaceutical agent or formulation ingredient, a polymer, and combinations thereof.

12. The sensing circuit of claim 10, wherein the at least one sensing element is sensitive to a biological agent selected from a bacterium, a virus, a viral vector, a cell, an exosome, an extracellular vesicle, a cellular organelle or cell fragment, an antibody, a protein, a glycoprotein, a nucleic acid, an antigen, a tumor antigen, a sugar, an oligosaccharide, a polysaccharide, a lipid, a glycolipid, a sphingolipid, a vaccine, and combinations thereof.

13. The sensing circuit of claim 10, wherein the at least one sensing element comprises one or more of a thermistor, an infrared detector, a thermocouple, a resistance temperature detector, semiconductor temperature sensors, a current output temperature sensor, a voltage output temperature sensor, a resistance output silicon temperature sensor, a diode temperature sensor, a digital output temperature sensor, or a combination thereof.

14. The sensing circuit of claim 10, wherein the at least one sensing element comprises one or more of a capacitive humidity sensor, a resistive humidity sensor, a thermal conductivity humidity sensor, or a combination thereof.

15. The sensing circuit of claim 10, wherein the at least one sensing element comprises one or more of a scintillation detector, a gamma camera, a gaseous ionization detector, a Geiger Mueller tube, a semiconductor radiation detector, a silicon detector, a diamond detector, a germanium detector, a cadmium telluride detector, a cadmium zinc telluride detector, or combinations thereof.

16. The sensing circuit of claim 10, wherein the at least one sensing element comprises one or more of an image sensor, a charge-coupled device (CCD), an electron-multiplying CCD, a complementary metal-oxide-semiconductor (CMOS), a back-illuminated CMOS, a fiber optic intensity sensor, a fiber optic phase sensor, a fiber optic frequency sensor, a fiber optic polarization sensor, a photoelectric through-beam sensor, a photoelectric retro-reflective sensor, a photoelectric diffuse reflection sensor, an infrared detector, an ultraviolet sensor, an x-ray sensor, a color sensor, an ambient light sensor, a proximity sensor, a photodiode, an avalanche photodiode, a phototransistor, a photomultiplier tube, a spectrometer, or combinations thereof.

17. The sensing circuit of claim 10, wherein the at least one sensing element comprises one or more of a microphone, a piezoelectric transducer, an ultrasonic sensor, an acoustic emission sensor, a surface acoustic wave sensor, a bulk acoustic wave sensor, a capacitive acoustic sensor, or combinations thereof.

18. The sensing circuit of claim 8, wherein the at least one sensing element includes an active or passive element that is sensitive to the parameter of interest.

19. The sensing circuit of claim 8, wherein the parametric frequency comb generator is coupled in series or in parallel with the at least one sensing element.

20. The sensing circuit of claim 8, wherein the sensing circuit is embodied or included in a sensing system.

21. The sensing circuit of claim 20, wherein the sensing system comprises one or more of a camera, a video camera, a telescope, a microscope, a mobile device, a hydrophone, a microphone, a climate control system, a cold chain monitoring system, a radioactivity monitoring system, an environmental monitoring system, a chemical monitoring system, a biological monitoring system, a chemical analysis system, a biological analysis system, a structural monitoring system, a structural analysis system, a medical device, an x-ray machine, an MRI, an ultrasound system, a motion detection system, a range-finding system, a localization system, a target acquisition system, a target tracking system, an object detection system, or combinations thereof.

22. The sensing circuit of claim 8, wherein the input comprises at least one of an input antenna or an input port and the output comprises at least one of a separate output antenna or a separate output port.

23. The sensing circuit of claim 8, wherein the input and output comprise at least one of a combination input/output antenna or a combination input/output port.

24. An RFID tag comprising:
a parametric frequency comb generator including:
a parametric oscillator;
an electromechanical resonator coupled to the parametric oscillator;
an input antenna for receiving an interrogation signal; and
an output antenna for transmitting a frequency comb, the output antenna either combined with or separate from the input antenna,
wherein the parametric frequency comb generator produces the frequency comb centered around an input frequency of the interrogation signal received by the input antenna, a multiple of the input frequency, or a fraction of the input frequency,
wherein a line spacing of the frequency comb is a function of the input frequency, a power of the interrogation signal received by the parametric frequency comb generator, a resonance frequency of the electromechanical resonator, or combinations thereof.

25. The RFID tag of claim 24, wherein the input antenna and the output antenna of the RFID tag are separate antennas.

26. The RFID tag of claim 24, wherein the input antenna and output antenna of the RFID tag are embodied in a combination input/output antenna.

27. The RFID tag of claim 24, further comprising at least one sensing element sensitive to a parameter of interest and coupled to the parametric frequency comb generator, wherein a change in the parameter of interest alters the line spacing of the frequency comb produced by the parametric frequency comb generator.

28. The RFID tag of claim 27, wherein the RFID tag is included in a sensing system.

29. The RFID tag of claim 28, wherein the sensing system comprises one or more of a camera, a video camera, a telescope, a microscope, a mobile device, a hydrophone, a microphone, a climate control system, a cold chain monitoring system, a radioactivity monitoring system, an environmental monitoring system, a chemical monitoring system, a biological monitoring system, a chemical analysis system, a biological analysis system, a structural monitoring system, a structural analysis system, a medical device, an x-ray machine, an MRI, an ultrasound system, a motion detection system, a range-finding system, a localization system, a target acquisition system, a target tracking system, an object detection system, or combinations thereof.

30. A method of detecting a presence, absence, or change of a parameter of interest comprising:
providing a sensing circuit for detection or measurement of a parameter of interest, the sensing circuit comprising:
a parametric frequency comb generator including:
a parametric oscillator;
an electromechanical resonator coupled to the parametric oscillator;
an input for receiving a pump signal; and
an output for transmitting a frequency comb, the output either combined with or separate from the input,
wherein the parametric frequency comb generator produces the frequency comb centered around an input frequency of the pump signal received by the input, a multiple of the input frequency, or a fraction of the input frequency,
wherein a line spacing of the frequency comb is a function of the input frequency, a power of the pump signal received by the parametric frequency comb generator, a resonance frequency of the electromechanical resonator, or combinations thereof; and
at least one sensing element sensitive to the parameter of interest and coupled to the parametric frequency comb generator, wherein a presence, absence, or change of the parameter of interest alters the line spacing of the frequency comb produced by the parametric frequency comb generator;
detecting, by the at least one sensing element, the presence, absence, or change of the parameter of interest;
receiving, at the sensing circuit, the pump signal having the input frequency;
outputting, via the sensing circuit, the frequency comb having an altered line spacing; and
determining, from the altered line spacing, a detected presence, absence, or change of the parameter of interest.
